(19) United States
(12) Patent Application Publication
(10) Pub. No.: US 2024/0133023 A1
(43) Pub. Date: Apr. 25, 2024

(54) HIGHLY HOMOGENEOUS GLASS SPUTTER TARGETS WITH LARGE ASPECT RATIO AND HIGH RELATIVE DENSITY FOR PHYSICAL VAPOR DEPOSITION

(71) Applicants: SCHOTT Corporation, Rye Brook, NY (US); SCHOTT AG, Mainz (DE); SCHOTT Japan Corporation, Shiga (JP)

(72) Inventors: James Marro, Duryea, PA (US); Yoshio Okano, Tokyo (JP); Azatuhi Ayrikyan, Alfortville (FR); William Preston, Duryea, PA (US)

(73) Assignees: SCHOTT Corporation, Rye Brook, NY (US); SCHOTT AG, Mainz (DE); SCHOTT Japan Corporation, Shiga (JP)

(21) Appl. No.: 18/392,422

(22) Filed: Dec. 21, 2023

Related U.S. Application Data
(63) Continuation of application No. PCT/US2022/073405, filed on Jul. 4, 2022.
(60) Provisional application No. 63/202,977, filed on Jul. 2, 2021.

(51) Int. Cl. C23C 14/34

(52) U.S. Cl. CPC C23C 14/3414

(57) ABSTRACT

The current disclosure relates to highly homogeneous glass sputter targets with a large aspect ratio and a high relative density. The glass sputter targets have properties that are desirable for forming thin films by physical vapor deposition processes such as sputtering.

### CROSS REFERENCE TO RELATED APPLICATIONS

This is a continuation of International Patent Application No. PCT/US2022/73405 filed on Jul. 4, 2022, which claims priority to U.S. Provisional Patent Application No. 63/202,977 filed on Jul. 2, 2021, all of which are incorporated herein by reference in their entirety.

### BACKGROUND OF THE DISCLOSURE

### 1. Field of the Disclosure

The current disclosure relates to highly homogeneous glass sputter targets with large aspect ratios and high relative densities. The glass sputter targets have properties that are desirable for forming thin films by physical vapor deposition processes such as sputtering.

### 2. Background of the Disclosure

Chalcogenides are materials that contain at least one chalcogen or group 16 element with the exception of oxygen. Sulfur, selenium, and tellurium are the common chalcogens. These elements are typically covalently bonded to network formers, such as Ge, Si, As, and Sb. Some chalcogenide compositions exhibit unique properties relevant for phase change materials and switching applications in memory storage, such as electric-field-induced crystalline filament growth. Metavalent bonding is thought to be responsible for the large change in resistance between the highly electrically resistant chalcogenide amorphous phase and the less electrically resistant chalcogenide crystalline phase. It is also attributed to resistance changes when exceeding an applied threshold voltage across amorphous chalcogenide materials. These properties make chalcogenide materials desirable for electronic applications.

Physical vapor deposition (“PVD”) is a commonly used process to deposit a thin film on a substrate. In the PVD process of sputtering, a physical vapor deposition apparatus having a source material (the “sputter target”) ejects atoms from the source material by bombardment with gas ions to deposit the thin film on the substrate. The sputter target may comprise a phase change material or ovonic threshold switch material that may be used in non-volatile random access memory. The sputter target may also comprise a support plate usually made of metal in contact with the sputter target. The support plate may be a useful component of the cooling system for the sputter target and the PVD apparatus.

Chalcogenide sputter targets are typically manufactured using a melting process to produce a bulk glass or ceramic, then the material is milled into a powder and the powder is sintered to produce the sputter target. This type of processing often results in a crystalline sputtering target that has a density lower than the desired theoretical density. Furthermore, improper processing leads to compositional inconsistency across the glass. The density and homogeneity of the target can be improved through optimization of the powder sizes and the sintering process, however, the relative density does not reach 100% of its theoretical value. The low relative density leads to a shorter lifecycle of the target while inhomogeneity will result in inconsistent film deposition. The crystalline nature of the sputter targets formed by sintering has also been shown to negatively impact the sputtered films.

U.S. Pat. No. 3,791,955 describes a process of preparing a chalcogenide sputter target by molding a chalcogenide material by sealing a boule of the material in an evacuated quartz system, placing a metal plunger on top of the boule to insert a metal mesh in the boule, and heating the resulting material in a furnace under vacuum or with a backfill of inert gas to create a temperature gradient vertically down the ampoule.

### SUMMARY OF THE INVENTION

The current disclosure relates to highly homogeneous glass sputter targets with large aspect ratios and high relative densities. The glass sputter targets have properties that are desirable for forming thin films by physical vapor deposition processes such as sputtering.

Some embodiments of the current disclosure relate to a sputter target comprising a support plate and a chalcogenide glass composition having an amorphous content greater than 90%. The support plate can act as a heat sink and can hold the target in place. The glass can directly contact the support plate or an adhesive can be used to secure them together. The chalcogenide glass composition can comprise 10-30 wt % of germanium, 2-40 wt % of arsenic, 30-80 wt % of selenium and 0.5-25 wt % of silicon. The chalcogenide glass composition can have an aspect ratio from 10 to 250 at a thickness from 1 to 20 mm and a diameter from 50 to 500 mm. In some embodiments, the chalcogenide glass composition has a compositional homogeneity of 5 at % or less and/or a relative density 0.990 or more. The amorphous chalcogenide glass composition can be prepared by melting chalcogenide raw materials in an ampoule at 700 to 1,200° C. to react the raw materials, rapidly cooling the reacted raw materials to form an amorphous material, annealing the amorphous material to reduce stresses produced during the cooling step, placing the annealed material in a hot forming apparatus comprising a mold, heating the top, bottom and sides of the material in the hot forming apparatus to a temperature between its glass transition temperature and its crystallization temperature, and deforming the material into the mold to produce the amorphous chalcogenide glass composition. The hot forming apparatus can be a slumping apparatus. A plunger or top plate can guide the material into the mold during the deforming step. A sensor can be used to detect the onset of glass deformation and heating can be held at that temperature until the glass is fully deformed. The heating step can conductively heat a top of the material using a plunger or top plate, conductively heat a bottom of the material through contact with a base plate, and convectively heat a side of the material using a heated gas flow.

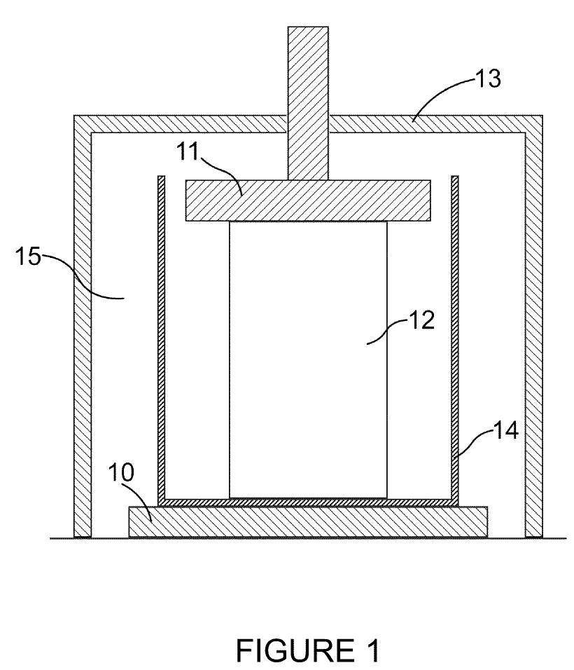

FIG. 1 is an image of a hot forming apparatus.

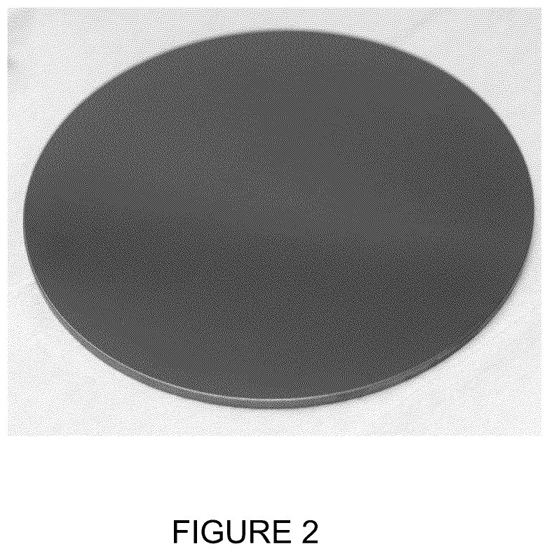

FIG. 2 is an image of the glass material from Example 1.

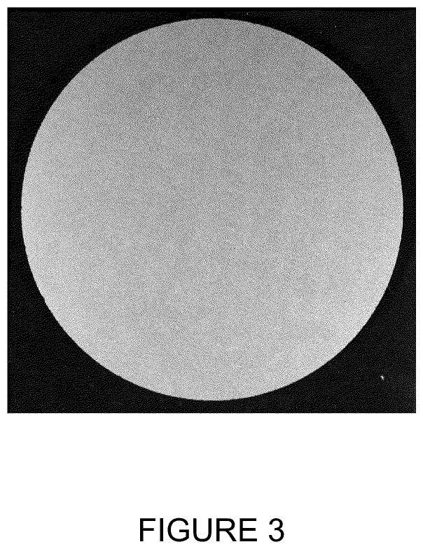

FIG. 3 is an image of the ceramic material from Example 2.

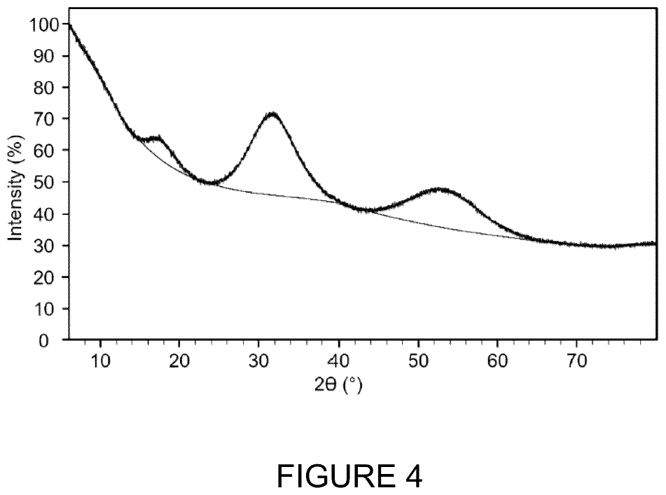

FIG. 4 shows the XRD data from Example 1.

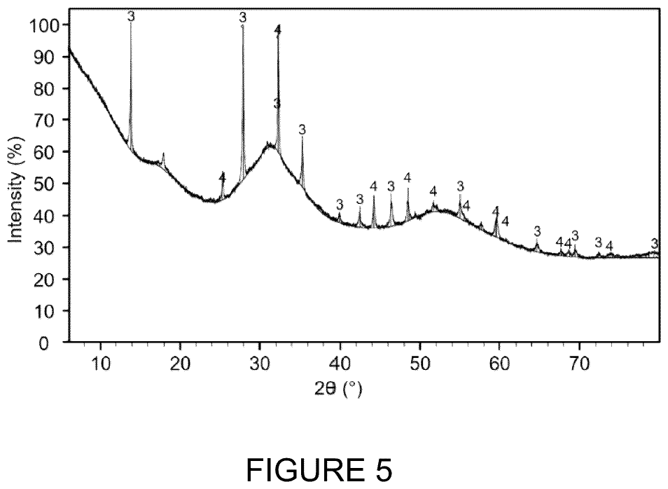

FIG. 5 shows the XRD data from Example 2.

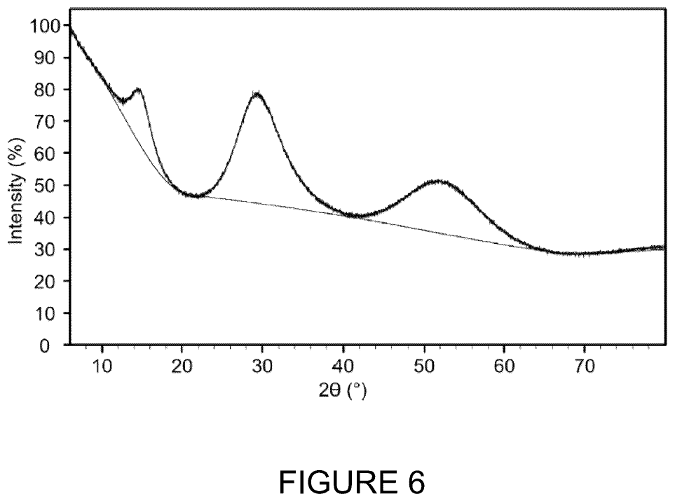

FIG. 6 shows the XRD data from Example 3.

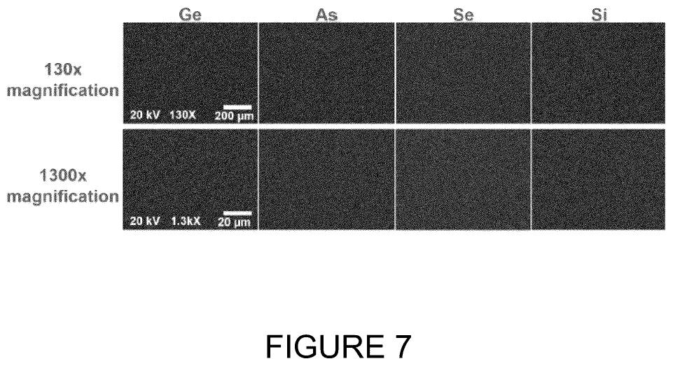

FIG. 7 shows the EDX images from Example 3.

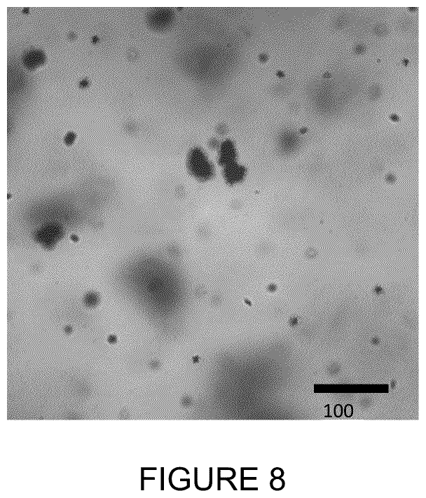

FIG. 8 shows the crystal formation from Example 4.

### DETAILED DESCRIPTION OF THE DISCLOSURE

The manufacturing method described in U.S. Pat. No. 3,791,955 along with other conventional sputter target manufacturing methods utilize conduction to heat and cool the chalcogenide boule from the top and the bottom. This type of heating has a relatively low efficiency and intentionally creates a temperature gradient across the material as noted in the '955 patent. The low thermal conductivity of chalcogenide materials accentuates this nonuniform heating behavior, making it very difficult to generate large aspect ratio glasses that are uniformly manufactured and homogeneous.

Such creation of a thermal gradient during chalcogenide material processing, whether intentional or not, results in several issues. The first is a higher potential to thermally shock the material during heating or cooling thereby causing it to fracture. Secondarily, a large thermal gradient results in differences in viscosity throughout the material and non-uniform forming of the material can occur. Some signs of non-uniformity include uneven thicknesses or shapes in the final material, or a crease on the sidewalls of the material due to the material folding in on itself. Any defect such as a crease will need to be removed, reducing the usable area of the material. Lastly, this type of inefficient non-uniform heating may result in a higher overall temperature or longer time needed to properly hot form the material. These are some of the reasons that may prevent the formation of high aspect ratio chalcogenide glass sputter targets.

The chalcogenide glass sputter target forming methods disclosed herein can alleviate many of these problems. The methods more uniformly control the temperature of the material during manufacture for example by utilizing temperature controlled gases to convectively heat the sidewalls of the chalcogenide glass while conductively heating the top of the chalcogenide glass for example through contact with a metal plunger and conductively heating the bottom of the glass for example through contact with a baseplate. The increased processing efficiency that results from these methods lowers the likelihood of encountering the issues mentioned previously. For instance, there is a decreased likelihood of part failure during the heating and cooling of the glass due to the higher degree of temperature distribution.

It is often critical to avoid excess temperature where possible. The processes described herein can assist in avoiding crystallization by minimizing the temperatures needed to hot form the chalcogenide glasses. Furthermore, the importance of temperature control shown herein illustrates the difficulty in producing chalcogenide glasses at large scales without crystalline content. Since chalcogenides have poor thermal and mechanical properties, cooling the glass fast enough to avoid crystallization becomes more challenging when the thermal mass is high. Producing these materials in a smaller format and hot forming to generate the necessary sizes becomes more manageable than increasing the melting scale.

The processes disclosed herein make it possible to generate highly dense chalcogenide glass sputtering targets with large aspect ratios and high volume homogeneity. Additionally, less of the starting materials must be scrapped since there is less likelihood of forming a crease and other defects. Still further, since lower temperatures and shorter processing times are possible, crystallization of the chalcogenide glass can be more easily avoided and the glass can have a single amorphous phase with little or no crystal phase. The result of these processes includes higher glass sputter target homogeneity and the potential to form high aspect ratio chalcogenide glass sputter targets. This is especially true for unstable glasses where the temperature required to viscously form the sputter target overlaps with the onset of crystallization.

The term “glass” used herein includes glasses and glass ceramics as opposed to ceramics. Ceramics are typically polycrystalline materials with a large majority of the volume having some crystallographic structure. Unlike ceramics, glasses are amorphous materials and glass ceramics are materials that have both an amorphous and crystalline phase where the amorphous phase is at least 50 vol % of the material.

In some embodiments, the methods disclosed herein can produce glass sputter targets having a relative density of 0.990 or more, 0.991 or more, 0.992 or more, 0.993 or more, 0.994 or more, 0.995 or more, 0.996 or more, 0.997 or more, 0.998 or more, or 0.999 or more; at a thickness from 1 mm to 20 mm, 1 mm to 15 mm, or 1 mm to 10 mm; in a circular format with a diameter from 50 mm to 500 mm, 100 mm to 500 mm, or 500 mm to 1,000 mm; with an aspect ratio from 10 to 250, 10 to 175, 25 to 150, 35 to 150, or 45 to 150; with an amorphous content of 90% or more, 95% or more, 99% or more, 99.5% or more, 99.6% or more, 99.7% or more, 99.8% or more, or 99.9% or more; and/or with a compositional homogeneity of 5 at % or less, 4 at % or less, 3 at % or less, 2 at % or less, or 1 at % or less, for any given component of the material. The amorphous content is measured by x-ray diffraction. In addition to these exemplary ranges, unless otherwise indicated, all subranges thereof are included as well. An illustrative example of a subrange is that a range of 1 mm to 20 mm includes all possible subranges such as 5 mm to 15 mm, 3 mm to 9 mm, and all other possible ranges that can be created.

The relative density is defined herein as the ratio of the measured density to the theoretical density of a material, where the theoretical density is the density of the material with no porosity, voids, or other defects present. The theoretical density can be calculated by knowing the crystal structure of the material; however, glasses do not have crystal structures and can have varying densities that depend on the synthesis parameters. Therefore, for glasses the relative density is determined with the following equation:

$$RD = 1 - \frac{{v}_{d}}{{v}_{t}}$$

, where RD is the relative density, vv_{dd} is the volume of pores and other defects in the material, and vvₜₜ is the total volume of the part being measured. The volume of defects is measured by transmitted light microscopy or optical imaging through the part. Many chalcogenide glasses do not transmit at visible wavelengths and require infrared imaging devices, such as those that utilize wavelengths from 1 μm to 12 μm.

The aspect ratio is defined herein as the ratio of the diameter of a material to its thickness. Compositional homogeneity is the variation in composition across the material. Amorphous content refers to the volume fraction of the amorphous matrix phase compared to the crystalline phase in the material.

The chalcogenide glasses of the current disclosure can be manufactured by one of the following exemplary melt-quench then hot forming processes.

A melt-quench process is used to react the raw materials and create a highly homogeneous glass boule. Preventing oxygen and water contamination during this process is important to maintain proper chemistry and the desired properties of the glasses. Therefore, process steps are usually taken to avoid exposure of the raw materials to air.

The batching process is conducted in a glovebox with an inert atmosphere, in which high purity chalcogenide raw materials (5N or better) are combined in a silica ampoule. The charged ampoule is then held under dynamic vacuum to create a negative pressure in the vessel. During this step, purification processes can be performed. Vacuum sublimation is commonly implemented to reduce any surface oxides and water. Next, the ampoule is sealed with a torch or heated ring. This closed system prevents extrinsic contaminants from the atmosphere which is important for material purity. The sealed material is then reacted and melted in a rocking furnace. Temperatures from 700 up to 1,200° C. are used to melt and homogenize the material.

In an attempt to lock in a highly amorphous state and form a homogeneous material, the melted material is cooled rapidly (quenched). Forced air or liquid cooling is employed to cool at the rates needed. If cooled too slowly, the atoms will arrange themselves to create crystalline phases within the amorphous matrix, resulting in a material with a low amorphous content. The properly cooled highly homogeneous material is then annealed in an oven to reduce stresses formed during the cooling process.

The density of the resulting material is dependent on the cooling rate. Uniform and consistent density is achieved through highly regulated cooling rates based on the glass transition temperature of the glass. However, large format parts can be difficult to cool uniformly from the melt temperature. Controlling the temperature properly will produce a highly dense and highly homogeneous glass boule.

Next, unlike the powder sintering techniques used in traditional sputtering target production, the hot forming processes disclosed herein exploit the amorphous nature of the material created during the melting process. A hot forming process such as extrusion, hot pressing, slumping, injection molding or reheat casting, inside or outside a furnace, can be used to produce the material. This is not feasible for crystalline materials produced by conventional sintering. In one such process of the current disclosure the cooled and highly amorphous glass is slumped in a slumping apparatus or in a furnace to form a large aspect ratio chalcogenide glass sputter target having the high relative densities and the high homogeneities described herein.

An exemplary slumping apparatus is shown in FIG. 1 and includes base plate 10, plunger 11, shell/enclosure 13, mold 14 and inert gas atmosphere 15. Chalcogenide glass boule 12 is contained therein. The slumping process deforms the glass under minimal force using a plunger or top plate for example using a force such as 5 to 50 lbf, or without a plunger or top plate under the weight of the glass itself. This process can be performed in a slumping instrument or in a furnace with vacuum or in a heated inert gas atmosphere. A controlled environment protects the material from oxygen or water contamination at elevated temperatures.

During the slumping process the boule of chalcogenide glass obtained from the melt quench process is arranged inside a mold and placed on the base plate of the slumping instrument or on the base plate in a furnace. The glass is slowly heated and isothermally held at a temperature between its glass transition and crystallization temperatures, typically close to the softening point of the glass (typically between 200° C. and 500° C.).

During the heating of the boule during the slumping process, a plunger or top plate can be used to guide the material during the deformation into the mold. A sensor can be used to detect the onset of glass deformation. When the glass initially begins to deform, the sensor can signal to hold the temperature (plus or minus a certain amount if desired) until the glass is fully deformed. Holding the temperature at the onset of deformation prevents an unnecessarily high temperature which reduces the likelihood of crystal formation. The furnace or shell of the slumping instrument ensure a closed environment and a uniform temperature during the slumping process.

During the slumping process, a heated gas flow can be implemented to heat and cool the glass from its sides and other areas. When the glass is slumped in a furnace, the heated inert gas is supplied into the furnace cavity and contacts at least the sides of the glass. When the glass is slumped in a slumping apparatus, the heated inert gas is supplied into a shell/container than encloses the slumping apparatus, or if no shell/container is used, then directly toward at least the sides of the glass. The shell/container may also be heated. The matched heating of the shell creates a thermal environment to make sure that the thermal energy in the gas is not affected by the mass of the shell. The heated inert gas that contacts the glass ensures that a more uniform temperature distribution is reached from the top to the bottom of the glass and allows for convective thermal energy transfer. The temperature of the plunger, base plate, and inert gas may be controlled to prevent a significant temperature gradient from occurring through the glass, for example less than about 50° C., less than about 40° C., less than about 30° C., less than about 20° C., less than about 10° C., or less than about 5° C. Simultaneous conductive heating of the top of the glass using the plunger and the bottom of the glass using the base plate while convectively heating the sides of the glass using the inert gas provide uniform temperature management. This type of efficient heating can prevent the glass from deforming unevenly and can allow for example 10 to 50° C. lower overall temperatures compared to the conventional processes. Therefore, crystal nucleation and growth can be more easily avoided during the process and a large aspect ratio glass sputter target having a high relative density and a high homogeneity can be produced.

A sensor can detect when the glass has fully deformed/slumped into the desired shape, then slow cooling can begin to avoid thermally shocking the glass. The glass can then be reannealed. The mold ensures the glass will conform to the proper near final desired aspect ratio.

The hot formed glass material may undergo further processing, such as cutting, grinding, and polishing, to generate a dimensionally precise sputtering target with the desired surface quality and aspect ratio.

Utilizing the manufacturing processes disclosed herein can produce high aspect ratio glass sputtering targets having a high amorphous content without the use of powder processing. The processes can yield nearly 100% theoretically dense monolithic amorphous materials, unlike conventional methods. The processes disclosed herein may be suitable for many glass types including chalcogenide glasses. Suitable chalcogenide glasses to produce the sputter targets disclosed herein include but are not limited to GeAsSeS, GeAsSeInSi, GeAsSeIn, and GeAsSeSi. Suitable weight percentages of the elements, if present in the composition, include but are not limited to Ge 10-35 wt %, As 2-40 wt %, Sb 1-20 wt %, Se 2580 wt %, In 1-40 wt %, Te 1-40 wt %, and/or Si 0.5-25 wt %.

### EXAMPLES

### Example 1

Over 5 kg of As₂Se₃ glass was synthesized by combining the proper amounts of As and Se in a 70 mm diameter ampoule. The materials were melted between 700 and 800° C. in a rocking furnace. The molten glass was then quenched to prevent crystallization and to create a homogeneous glass. Annealing was conducted to ensure residual stresses were reduced in the glass.

The glass was hot formed by slumping to a diameter of 136 mm. Slumping was performed in an actively heated nitrogen atmosphere. The temperature was increased slowly and the first sensor was triggered at about 238° C. when the glass began to deform. A 10° C. offset was introduced to ensure full slumping and the temperature was held until a completed slump was detected after approximately 4 hrs. The temperature of the glass was then slowly ramped down to room temperature. This rendered a glass part that was approximately 136 mm in diameter and 13 mm thick. The glass part was then mechanically processed to a diameter of 125 mm and thickness of 3 mm (aspect ratio >41). The glass part is shown in FIG. 2. The volume fraction of defects was so small that the relative density was effectively 1.

X-ray diffraction was performed with a Panalytical X'Pert MPD diffractometer. The measurements used Cu k-alpha irradiation at 40 kV and 40 mA on powder of the materials. As shown in FIG. 4, no peaks were observed in the diffraction pattern which indicated that no crystal content was contained in the material. At least 99.9 vol % of the glass was confirmed to be amorphous.

Samples were taken from different areas across the slumped glass material to check whether the composition varied spatially across the glass. A Bruker AXS S4 Pioneer X-Ray Flouorescence (XRF) spectrometer was used to measure the composition. Variations of only 0.18 at % As and 0.18 at % Se were observed across the slumped As₂Se₃ glass.

### Example 2

The commercially available As₂Se₃ ceramic sputter target shown in FIG. 3 was examined, available from ALB Materials Inc. with item number ALB-As₂Se₃-ST. The 5N purity target was 100 mm in diameter and 6 mm thick. It was expected that this ceramic sputter target was processed via a standard powdering sintering route as is common in the sputter target industry. Sintering is the densification of a powder, typically by applying a pressure and heat. Pores are often an unwanted byproduct of sintering. While there are methods and modifications that can reduce the porosity, it is difficult to achieve a fully dense ceramic part with a high relative density. The relative density was measured to be 0.952.

X-ray diffraction was performed in the same manner as Example 1. As shown in FIG. 5, both amorphous and crystalline features present in XRD pattern. Less than 90 vol % of the glass was amorphous and the value was roughly estimated to be about 75 vol %.

The compositional homogeneity was determined in the same manner as Example 1. A variation of 0.88 at % As and 0.88 at % Se was recorded.

### Example 3

A Ge—As—Se—Si glass composition was synthesized in a similar manner as Example 1. A 2 kg batch was melted at 1,000° C. for 8 hours in an ampoule with a 70 mm diameter. The glass material was quenched and annealed accordingly. The glass was slumped at 415° C. for 10 hours to generate a glass part measuring 136 mm in diameter and 16 mm thick. The glass part was mechanically processed down to 125 mm in diameter and 3 mm thick. The volume fraction of defects was so small that the relative density was effectively 1.

X-ray diffraction was performed in the same manner as Example 1. As shown in FIG. 6, no peaks were observed which indicates that no crystals were detected in the glass, i.e. it was 100% amorphous.

Samples were taken from different areas across the glass material to check whether the composition varied spatially across the slumped glass. The following variations were recorded: Ge: 0.20 at %, As: 0.20 at %, Se: 0.28 at % and Si: 0.21 at %.

A sample of the glass was analyzed on a Hitachi S-4700 scanning electron microscopy (SEM) with an IXRF model 550i energy dispersive x-ray spectroscopy (EDX) system. EDX showed further evidence of the compositional homogeneity achieved. Phase separation within the material was not observed and a highly uniform distribution of each element was recorded as shown in FIG. 7.

### Example 4

A Ge—As—Se—Si glass composition was synthesized in a similar manner as Example 3, except that the glass was slumped at 450° C., approximately 35° C. higher than Example 3. Due to the higher temperature of the slump, crystal formation was observed in the glass with a SWIR microscope as shown in FIG. 8. This demonstrated that some chalcogenide glass compositions can be relatively unstable and have small temperature windows in which the glass viscosity is low enough to achieve deformation without crystal nucleation and growth.

1. A sputter target comprising a support plate and a chalcogenide glass composition having an amorphous content of 90% or more.

2. The sputter target of claim 1, wherein the chalcogenide glass composition comprises 10-35 wt % of germanium, 2-40 wt % of arsenic, 1-20 wt % of antimony, 25-80 wt % of selenium, 1-40 wt % os indium, 1-40 wt % of tellurium, and/or 0.5-25 wt % of silicon.

3. The sputter target of claim 1, wherein the chalcogenide glass composition has an aspect ratio from 10 to 250 at a thickness from 1 to 20 mm and a diameter from 50 mm to 500 mm.

4. The sputter target of claim 1, wherein the chalcogenide glass composition has a compositional homogeneity of 5 at % or less.

5. The sputter target of claim 1, wherein the chalcogenide glass composition has a relative density of 0.990 or more.

6. A chalcogenide glass composition comprising 10-35 wt % of germanium, 2-40 wt % of arsenic, 1-20 wt % of antimony, 25-80 wt % of selenium, 1-40 wt % os indium, 1-40 wt % of tellurium, and/or 0.5-25 wt % of silicon, wherein the chalcogenide glass composition has an amorphous content of 90% or more.

7. The chalcogenide glass composition of claim 6, wherein the chalcogenide glass composition has an aspect ratio from 10 to 250 at a thickness from 1 to 20 mm and a diameter from 50 to 500 mm.

8. The chalcogenide glass composition of claim 6, wherein the chalcogenide glass composition has a compositional homogeneity of 5 at % or less.

9. The chalcogenide glass composition of claim 6, wherein the chalcogenide glass composition has a relative density of 0.990 or more.

10. A sputter target comprising a support plate and the chalcogenide glass composition of claim 6.

11. A chalcogenide glass composition having an amorphous content or 90% or more and an aspect ratio from 10 to 250 at a thickness from 1 to 20 mm and a diameter from 50 to 500 mm.

12. A method for producing an amorphous chalcogenide glass composition, the method comprising the steps of:
a) melting chalcogenide raw materials in an ampoule at 700 to 1,200° C. to react the raw materials;
b) rapidly cooling the reacted raw materials to form an amorphous material;
c) annealing the amorphous material to reduce stresses produced during the cooling step;
d) placing the annealed material in a hot forming apparatus comprising a mold;
e) heating the top, bottom and sides of the material in the hot forming apparatus to a temperature between its glass transition temperature and its crystallization temperature; and
f) deforming the material into the mold to produce the amorphous chalcogenide glass composition.

13. The method of claim 12, wherein the hot forming apparatus is a slumping apparatus.

14. The method of claim 12, wherein a plunger or top plate guides the material into the mold during the deforming step.

15. The method of claim 12, wherein a sensor detects the onset of glass deformation and heating is held until the glass is fully deformed.

16. The method of claim 12, wherein the heating step conductively heats a top of the material using a plunger or top plate, conductively heats a bottom of the material through contact with a base plate, and convectively heats a side of the material using a heated inert gas flow.
